(19) United States
(12) Patent Application Publication
(10) Pub. No.: US 2003/0011397 A1
(43) Pub. Date: Jan. 16, 2003

(54) Method for monitoring the radial gap between the rotor and the stator of electric generators and device for carrying out said method

(76) Inventors: Dieter Briendl, Baden (CH); Hermann Scheil, Hemhofen (DE)

Correspondence Address: HARNESS, DICKEY & PIERCE, P.L.C., P.O.BOX 8910, RESTON, VA, 20195, US

(21) Appl. No.: 10/168,299

(22) PCT Filed: Dec. 7, 2000
(86) PCT No.: PCT/DE00/04361

(30) Foreign Application Priority Data
Dec. 20, 1999 (DE) 199 61 528.4

(51) Int. Cl. G01R 31/06; G01R 31/34

(52) U.S. Cl. 324/772; 324/546; 324/545

(57) ABSTRACT

The invention relates to a method for monitoring the radial gap (10) between the rotor (6) and the stator (8) of an electric generator (2). The aim of the invention is to provide a method that allows an especially reliable analysis of the shape of the radial gap (10) during operation of the generator (2). To this end, a measuring cycle is carried out in the stationary and balanced operating mode of the generator at defined intervals. In every measuring cycle, current parameters (120) of the radial gap (10) are determined from current marginal values (50) of the generator (2), from current influential values (80) of the generator (2) and from current measuring data (100). These parameters are used to determine and evaluate the shape of the radial gap (10) and the distance between the rotor (6) and the stator (8) by comparing them with reference parameters. The inventive method allows to better predict when repairs have to be made.

The invention relates to a method for monitoring the radial gap between the rotor and the stator of an electrical generator. It also relates to an apparatus for carrying out the method.

The radial gap between the rotor and the stator of a generator is in the form of a concentric, annular circular cylinder. In this case, the outer envelope is formed by the laminated core of the stator and the inner envelope is formed by the surface of the poles on the rotor, with the largest rotor diameter being the governing factor.

The size of the radial gap, which is the governing factor for the magnetic field or for the excitation requirement, is normally very small in comparison to the diameter of the stator inner wall, and, for example in the case of generators which have a rotor diameter of 16 m is about 0.2% of the diameter of the stator inner wall. A magnetic interaction takes place between the rotor and the stator across the radial gap. The magnetic forces in this case amplify any existing static and/or rotating asymmetries since a radial gap which is particularly small locally results in a comparatively larger magnetic field locally. This situation results in greater forces, which can cause further asymmetric deformation, depending on the mechanical stiffness of the generator. Suitable generator design, construction and production steps should therefore be taken in order to ensure that the shape of the radial gap between the rotor and the stator is as ideal as possible.

The shape of the radial gap between the rotor and the stator when the rotor is stationary is governed by tolerances which occur during manufacture and assembly. In this case, it should be remembered that the shape of the stator inner wall is not normally in the form of an ideal circle but differs at least slightly from this ideal circle and the differences are not distributed uniformly around the axis. Centrally symmetrical deformations frequently occur in this case, such as ovality, and deformations with six or eight nodes (cloverleaf). Other asymmetries can likewise occur, for example caused by supporting elements such as star arms and the like. Viewed axially, the mean air gap may also vary, for example due to a local constriction of the stator center. Deformations of this type can occur in the event of shrinkage processes and seating processes with vertically arranged stators. Asymmetric deformations are characterized predominantly by curvature, which means that the geometric centers do not lie on a straight line when viewed axially. Furthermore, the shape of the rotor is normally not ideal either, for example individual poles may project or be recessed, even packet-by-packet, on the rotor of so-called multipole machines.

The shape of the radial gap may also vary due to the operation of the generator and environmental influences. The radial gap differs considerably from the ideal shape if the rotor axis and the stator axis are not parallel. Both a parallel shift and oblique positioning of the rotor axis relative to the stator axis can be observed in this case. Such a discrepancy can occur when, after the generator has been in operation for a lengthy time, the alignment of the rotor relative to the stator changes, play occurs in the supporting elements, foundation influences become noticeable, and shrinkage processes occur in the concrete, resulting in shifts in the base and/or bed. The alignment of the rotor axis relative to the stator axis is also influenced by bearing play in the rotor bearing.

Furthermore, the rotation speed of the rotor during operation of the generator can result in the rotor diameter being enlarged by centrifugal forces. In this case, particularly when the generator is first started up, that is to say during commissioning and during the overspeed test, non-elastic deformation of the rotor can be observed, as well as a permanent change, associated with this, in the radial gap between the rotor and the stator of the generator. The magnetic forces, which are normally constant during operation of the generator, also result in the size of the radial gap being reduced in comparison to the shape of the radial gap when the rotor is stationary.

The rotor temperature is dependent on the field current, on the mechanical losses resulting from friction, and on the cooling of the rotor. Furthermore, the rotor temperature is dependent on the stator temperature, since the rotor and stator are normally coupled via a cooling circuit. When transient operating states occur, for example, load changes, thermal time constants of, for example, 3 to 10 hours thus occur. With respect to the rotor temperature and the stator temperature, it should thus be remembered that these temperatures can cause asymmetric deformations of the rotor. This can be caused, for example, by severely asymmetric cooling.

Particularly in the case of large generators, for example, hydroelectric generators with rotor diameters of more than 5 m, there is a risk of the rotor not moving concentrically in the center of the stator. In this case, both the shape of the rotor and of the stator may vary, as well as their relative position with respect to one another. This results in large forces which are not distributed uniformly around the circumference of the rotor, and in some cases to vibration or oscillations. In the worst case, this can lead to the rotor coming into contact with the stator during operation of the generator, and this is associated with severe damage and long generator downtimes.

Conventional monitoring methods for the radial gap between the rotor and the stator of a generator do not provide any information about the instantaneous shape of the radial gap during operation of the generator. The laminated core of the stator is normally monitored for vibration and oscillations, but such monitoring can only partially detect changes to the shape of the radial gap between the rotor and the stator.

The invention is thus based on the object of specifying a method for monitoring the radial gap between the rotor and the stator of an electrical generator, which reliably ensures that the shape of the radial gap is analyzed and that the distance between the stator and the rotor is monitored during operation of the generator. This is intended to be achieved with particularly little technical complexity using an apparatus which is suitable for carrying out the method.

With respect to the method of the type mentioned initially, the object is achieved, according to the invention, in the following steps:

1. Influencing variables which govern the operating state are in each case recorded, basic measurements are carried out, and basic reference characteristic variables for the intact air gap geometry measured in the respective operating state are formed in advance for various defined operating states.

2. During subsequent operation, the size of the radial gap is recorded at a number of measurement points, which are distributed around the circumference of the machine, and at least one instantaneous influencing variable of the instantaneous operating state is recorded.

3. The variables obtained in step 2 are used to form instantaneous characteristic variables, and the basic reference characteristic variables obtained in step 1 are used to form instantaneous reference characteristic variables, which correspond to an intact air gap for the instantaneous values of the influencing variables.

4. At least the instantaneous characteristic variables obtained in step 3 are compared with the corresponding instantaneous reference characteristic variables of the radial gap; and if at least one of the instantaneous characteristic variables differs from the reference characteristic variable by more than a specified amount, a warning is produced.

The instantaneous measurement data is advantageously recorded when the electrical machine is in a steady and equilibrium operating state. This means that the operating parameters of the electrical machine should be in a steady state and that all the compensation processes which are initiated by a change in the operating state should be completed. Recording of the instantaneous measurement data in an operating state other than a steady state and/or in a non-equilibrium operating state would provide only an instantaneous record of the shape of the radial gap. It would thus not be possible to draw any reliable conclusions relating to any disturbance to the air gap geometry.

In a further refinement of the invention, the instantaneous measurement data and influencing variables are recorded cyclically, and both the instantaneous characteristic variables and the corresponding instantaneous reference characteristic variables are formed in each measurement cycle. This results in effectively continuous monitoring of the radial gap. It is thus possible to identify a dangerous disturbance to the air gap geometry, and possibly to initiate countermeasures, at virtually any time during operation of the electrical machine.

At least one of the following operating parameters of the electrical machine is advantageously recorded as an influencing variable:

the currents (Iᵤ, Iᵥ, I_{w}) flowing in the windings on the stator,

the current (I_{E}) flowing in the winding on the rotor,

the temperature (T_{LK}) of the cold cooling air (L) flowing to the stator.

The influencing variables which have been mentioned are the major variables which firstly govern the operating state of the machine and secondly influence the shape of the radial gap. The instantaneous reference characteristic variables can be formed from a knowledge of the physical relationships between the influencing variables and the shape of the radial gap.

In a further advantageous refinement of the invention, a mathematical method for Fourier analysis is applied to first mathematical vectors which, for each measurement point, contain the instantaneous measurement values of the air gap between the stator and the rotor poles moving past it during one revolution.

The formation of such a first vector is described by way of example in the following text.

The number of measurement points is assumed to be n, and it is assumed that an index i which is associated with the measurement points, may be in the value range i=1 . . . n.

The number of rotor poles is assumed to be r, and an index j which is associated with the rotor poles is assumed to be in the value range j=1 . . . r.

In consequence, instantaneous measurement values mᵢⱼ are produced at each measurement point i during one revolution of the rotor, with the instantaneous fixed value of the index i describing the measurement point under consideration.

The vector to be formed from this is referred to as v1:

vᵢ=└mᵢ₁mᵢ₂ . . . mᵢᵣ┘

Then, as mentioned above, a Fourier analysis method is applied to such first vectors.

At least one of the coefficients calculated on the basis of the Fourier analysis is used to form at least one instantaneous characteristic variable. Corresponding basic reference characteristic variables are obtained for the radial gap by corresponding application of Fourier analysis to the basic measurement values. The mathematical Fourier analysis methods are known; this form of analysis is a harmonic analysis which determines the DC component which may be present in the input data, as well as the harmonic oscillation components which it contains. The coefficients calculated by Fourier analysis may be interpreted as characteristic geometric variables.

The first coefficient, which corresponds to the DC component of the Fourier analysis, the second coefficient, which corresponds to the fundamental frequency, and the third coefficient, which corresponds to the first harmonic, are advantageously used to form further instantaneous characteristic variables. The mean value of the first coefficients which are calculated for each vector in this case describes the mean size of the radial gap, the mean value of each of the second coefficients describes the mean shift of the rotor axis relative to the axis of the stator (“eccentricity of the rotor”), and the mean value of each of the third coefficients describes the mean deformation of the rotor (“ovality of the rotor”). The characteristic variables for the radial gap which are formed using the Fourier coefficients thus intrinsically characterize the shape of said gap.

In a further advantageous refinement of the invention, the already determined characteristic variables are used to derive an auxiliary characteristic variable which makes it possible to estimate whether the further instantaneous characteristic variables describe the deformation of the rotor sufficiently accurately. From the mathematical point of view, this is an estimate of the so-called remaining terms in the Fourier analysis, which are not used to form characteristic variables.

If the values of the auxiliary characteristic variable are significant, at least one requirement characteristic variable is advantageously formed from at least one further coefficient obtained by means of the Fourier analysis. This requirement characteristic variable in this context provides information about any deformation of the rotor which is not covered by the already formed characteristic variables for the radial gap.

A mathematical Fourier analysis method is advantageously applied to a second mathematical vector having vector components which each correspond to one measurement point and each of which contains the mean value of the size of the radial gap associated with a measurement point. At least one additional instantaneous characteristic variable is formed from at least the second coefficient calculated on the basis of the Fourier analysis; corresponding instantaneous reference characteristic variables of the radial gap are obtained by corresponding application of the Fourier analysis to the averaged basic reference variables associated with each measurement point. The formation of such a second vector is described by way of example in the following text with the meanings of the variables i, r, j, n and mᵢⱼ as have already been described in another advantageous embodiment of the invention. The mean value of the size of the radial gap associated with a measurement point i is referred to as dᵢ and is formed as follows:

$${d}_{i} = \frac{1}{r} {\sum }_{j = 1}^{r} {m}_{ij}$$

A second mathematical vector—which is referred to as w—is then formed as follows:

w=└d₁d₂ . . . dₙ┘

A Fourier analysis method is then applied to one such second vector, as mentioned above.

In a further advantageous refinement of the invention, the additional instantaneous characteristic variables are formed from the second and third coefficients calculated on the basis of the Fourier analysis of the second vector. The second coefficient in this case describes the shift of the stator axis relative to the axis of the rotor (“eccentricity of the stator”), and the third coefficient describes the deformation of the stator (“ovality of the stator”).

The instantaneous measurement data for the radial gap is advantageously recorded in a measurement plane the normal to whose surface is oriented parallel to the shaft of the rotor. If the stator height of the electrical machine is large in comparison to the diameter of the stator, then the instantaneous measurement data may be recorded in a number of measurement planes.

In a further advantageous refinement of the inventions, at least one critical variable is also recorded in addition to the influencing variables which describe the instantaneous operating state of the electrical machine. Critical variables in this context are variables which are not influencing variables, that is to say variables which do not directly significantly influence the shape of the radial gap.

At least one of the following variables is advantageously recorded as a critical variable:

the temperature (T₁₆) of the laminated stator core,

the temperature (T₁₈) of the stator winding,

the temperature (T_{LW}) of the hot cooling air, flowing away from the stator,

the temperature (T_{WK}) of the cold cooling water before it enters the stator winding,

the temperature (T_{WW}) of the warm cooling water emerging from the winding on the stator,

the temperature of the rotor winding,

the wattless component of the electrical machine,

the real power of the electrical machine.

These critical variables can advantageously be used for more detailed analysis of the instantaneous characteristic variables of the radial gap.

At least each measurement of the instantaneous measurement data, of the influencing variables and of the critical variables as well as all the characteristic variables determined for one measurement are advantageously documented. Thus, for example, a trend analysis of the various variables can be carried out using all the data over a lengthy time period. Furthermore, various statistical analyses of the data material can be carried out.

According to one particular variant of the invention, the stated object is achieved in that a measurement cycle is carried out repeatedly when the generator is in a steady and equilibrium operating state, in which case, during the measurement cycle:

instantaneous influencing variables of the generator are recorded,

instantaneous measurement data is recorded for the radial gap and instantaneous critical variables are recorded for the generator,

instantaneous characteristic variables for the radial gap are determined from the instantaneous critical variables for the generator, from the instantaneous influencing variables for the generator and from the instantaneous measurement data for the radial gap, and

the shape of the radial gap and the distance between the rotor and the stator are determined and assessed by comparing the instantaneous characteristic variables for the radial gap with reference values from a number of basic measurements.

The invention is in this case based on the idea that the shape of the radial gap between the rotor and the stator should be recorded and analyzed during operation of the generator, in order reliably to monitor the distance between the rotor and the stator. The operating state of the generator has an effect on the instantaneous geometry of the radial gap; for example, dynamic load changes or static asymmetric loads which generally occur rather briefly on the electrical side of the generator lead to mechanical force conditions which in general act asymmetrically on the stator and on the rotor and thus change the geometry of the gap, which is physically defined for a normal, equilibrium operating state. This change to the gap geometry in the operating conditions mentioned above by way of example does not, however, represent an unacceptable or dangerous discrepancy from the characteristic variables for a reference measurement of the gap geometry which are desirable by virtue of the design and are recorded for a normal, equilibrium operating state. The design of the generator also provides for such operating conditions and the changes to the gap geometry which result from them do not represent a disturbance which needs to be observed and/or overcome. In order to reliably make it possible to deduce an unacceptable or dangerous discrepancy in the characteristic variables measured in an instantaneous operating state by comparison with reference characteristic variables, the instantaneous operating state must therefore also be recorded, and must be included in the analysis of the discrepancy.

Furthermore, changes to the generator, which may have a negative effect on the shape of the radial gap, should be identifiable at an early stage in order that they can be rectified. Changes to the generator can be detected by means of the influencing variables and the critical variables. The influence of the critical variables and influencing variables of the generator on the shape of the radial gap should thus be recorded and assessed in order to obtain information from these variables in good time on any change to the shape of the radial gap, allowing the causes to be found. For this purpose, instantaneous characteristic variables of the radial gap are determined from instantaneous critical variables and influencing variables for the generator, and from instantaneous measurement data for the radial gap.

The radial gap should be monitored virtually continuously in order that a statement about the shape of the radial gap and about the distance between the rotor and the stator can be made at any time during operation of the generator. A measurement cycle has been found to be suitable for this purpose, with whose aid all the variable influencing variables are checked cyclically at regular time intervals, and are checked to determine whether the generator is in a thermally steady state, that is to say it is in a steady and equilibrium state. If the generator is in a thermally stable state, then the shape of the radial gap should be analyzed, and the distance between the rotor and the stator should be monitored. To do this, once the influencing variables have been checked, instantaneous measurement data for the radial gap is read and is assessed by means of a comparison of the instantaneous characteristic variables for the radial gap with reference values from a number of basic measurements.

The shape of the radial gap is intended to be analyzed with the aid of the instantaneous characteristic variables for the radial gap, so that any deformation of the radial gap between the stator and the rotor, in particular any such deformation which is dangerous to the operation of the generator, can be identified at an early stage. In this case, the aim is to identify particularly reliably any discrepancy in the shape of the radial gap from the ideal shape. This is advantageously done by determining and assessing the shift of the stator relative to the axis of the rotor, and determining and assessing the deformation of the stator and of the rotor, by means of a comparison of the instantaneous characteristic variables for the radial gap with reference values for the generator.

The critical variables are advantageously temperature values at different locations on the stator, the temperature value on the winding on the rotor, the real power of the generator and the wattless component of the generator. In this case, the temperature values of the stator are advantageously the temperature value on the laminated core, the temperature value on the winding on the stator, the temperature value of the cooling air flowing away from the stator and which has been heated in the stator, the temperature value of the cold cooling water before it enters the winding on the stator, and the temperature value of the cooling water, which has been heated in the stator, after it emerges from the winding on the stator. These critical variables can be measured particularly easily during operation of the generator and provide a particularly reliable characterization of the operating state of the rotor and of the stator.

The influencing variables are advantageously the current and the voltage of the stator, the field current and the rotation speed of the rotor and the temperature value of the cold cooling air flowing to the stator. The voltage of the stator and the rotation speed of the rotor are normally constant when the generator is in a steady operating state. The current in the stator may in this case comprise three separate current elements, when the stator is operated using three-phase current. In this case, the winding on the stator then also comprises three winding elements, which are fed with the current elements separately. The stator current, the field current of the rotor and the temperature of the cold cooling air flowing to the stator have a long-term influence on the shape of the rotor and its position relative to the stator, and are therefore particularly suitable for use as influencing variables.

The instantaneous measurement data for the radial gap is advantageously determined in a measurement plane which is at right angles to the rotation axis of the rotor. This means that the number of sensors required for particularly reliable recording of the shape of the radial gap between the stator and the rotor is particularly small. The number of sensors is thus defined such that it is sufficient to reliably record all stator deformations which are dangerous to the generator. For example, stator ovality can reliably be recorded using six measurement locations. However, four measurement locations are frequently sufficient in this case, since the probability of all the measurement locations being located at a deformation node is very low. Four measurement locations are normally used if the diameter of the laminated core is less than 8 m, and eight sensors are used if the bore diameter is more than 8 m. If the stator height is particularly small in relation to the diameter of the stator, one measurement plane has been found to be sufficient. This is normally applied to the upper stator end, assuming that the generator axis is vertical, since this is where the greatest deformations of the radial gap can be expected. However, it has also been found to be worthwhile to place the measurement plane in the center of the stator since this is where the seating processes which result from the magnetic forces during operation of the generator lead to the possibility of the radial gap becoming smaller during operation of the generator. In the case of generators whose stator height is particularly large in comparison to this, it is furthermore possible to record changes in the axial direction, for example oblique positioning of the rotor axis relative to the stator axis, by means of a further measurement plane.

Each measurement cycle is advantageously documented. This makes it possible to carry out trend analyses in particular of measurement data for the radial gap, influencing variables and critical variables, so that it is possible to identify changes to the generator over the course of time. This documentation allows the causes of changes to the generator to be identified and rectified at an early stage.

With regard to the apparatus for monitoring the radial gap between the rotor and the stator of an electrical generator, the stated object is achieved according to the invention in that a number of sensors are provided in order to record instantaneous critical variables for the generator, instantaneous influencing variables for the generator, and instantaneous measurement data for the radial gap on the generator, with the sensors being connected, for data transmission purposes, to a processing module which is provided in order to produce instantaneous characteristic variables from the instantaneous critical variables for the generator, from the instantaneous influencing variables for the generator and from the instantaneous measurement data for the radial gap, with the processing module being connected, for data transmission purposes, to an analysis module, in which case the analysis module can control a measurement cycle for analysis of the shape of the radial gap and for monitoring the distance between the rotor and the stator.

This apparatus makes it possible to analyze the shape of the radial gap and to monitor the distance between the rotor and the stator with a particularly small number of components.

A memory module which is connected to the analysis module for data transmission purposes is advantageously provided for documentation of the generator data being recorded at any given time. The stored values allow trend calculations to be carried out, and provide information for diagnostic purposes. In this case, record printouts of the instantaneous values can be produced automatically. A representation can also be provided by means of freely configurable graphics for all the stored reference values and for the recorded data.

The advantages achieved by the invention are, in particular, that up-to-date recording of the influencing variables, critical variables and measurement data in the course of a repeatedly occurring measurement cycle particularly reliably ensures that the shape of the radial gap between the rotor and the stator of the generator can be analyzed and that the distance between the rotor and the stator can be monitored. This makes it possible to identify changes in the shape of the radial gap between the rotor and the stator of the generator at an early stage, so that influences which are damaging to operation of the generator can be identified and rectified at an early stage.

An exemplary embodiment of the invention will be explained in more detail with reference to a drawing, with parts which correspond to one another in all the figures being provided with the same reference symbols.

### IN THE DRAWING

FIG. 1 shows, schematically, an apparatus for carrying out the method for monitoring the radial gap between the rotor and the stator of an electrical generator, and

FIG. 2 shows, schematically, a cross section through the rotor and the stator as shown in FIG. 1.

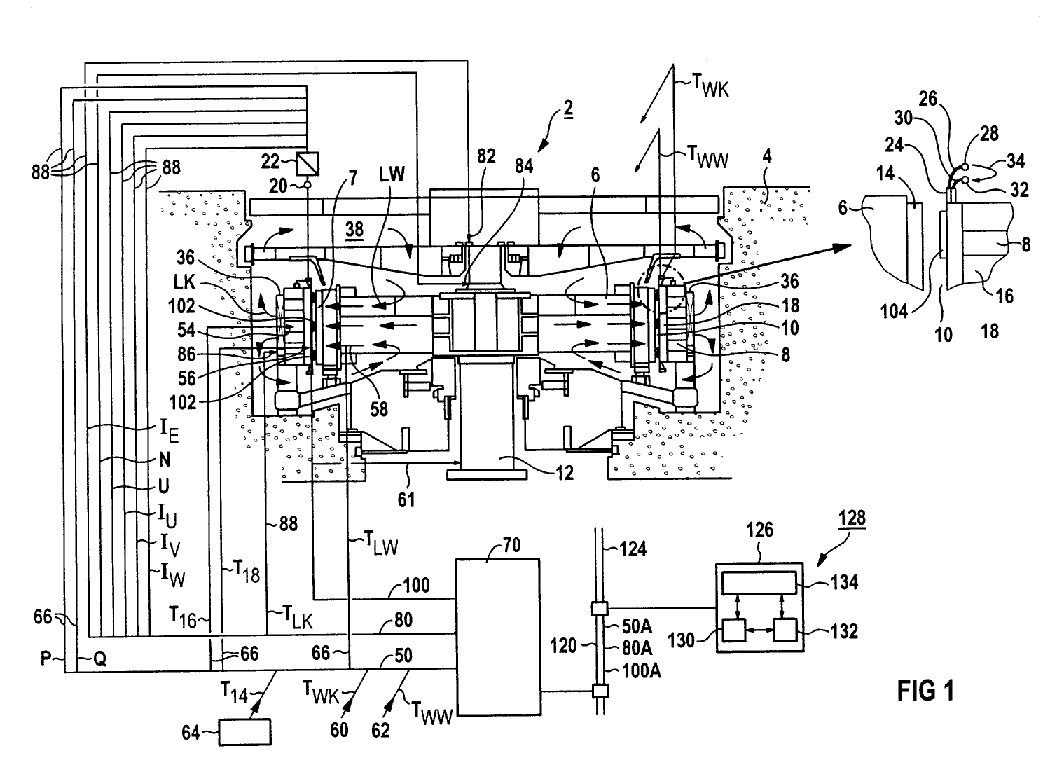

The generator 2, which is illustrated schematically in the form of a longitudinal section in FIG. 1, is in the form of a hydroelectric generator and, in a housing 4, has a rotor 6, which is concentrically surrounded by a stator 8. The rotor 6 and the stator 8 are separated from one another by a radial gap 10. The rotor 6 has a shaft 12, a winding 14 provided for the field current I_{E} for the rotor 6, and numerous poles, which are not illustrated in any more detail in the drawing. The stator 8 has a laminated core 16 and a winding 18. The winding 18 on the stator 8 is connected via connecting terminals 20 to isolating amplifiers 22, which are connected to measurement circuits, although the measurement circuits are not illustrated in the drawing.

The winding 18 on the stator 8 has three separate windings U, V and W which are not illustrated in the drawing. Each of the three separate windings U, V and W in turn comprises winding bars 24, which are electrically connected in series and only some of which are shown in the drawing. Each winding bar 24 or a number of conductor elements (which are not shown in the drawing) of each winding bar 24 has, or have, cooling water flowing through it or them during operation of the generator 2. In order to supply cold cooling water WK, the winding bars 24 of the winding 18 are connected on the input side via insulating plastic hoses 26 to a first ring line 28. In order to carry away the cooling water WW, which is heated in the winding bars 24 of the winding 18 during operation of the generator 2, the winding 18 on the stator 8 is connected on the output side via plastic hoses 30 to a second ring line 32. In order to cool down the cooling water WW which has been heated in the winding 18, the second ring line 32 is connected (in a manner which is not illustrated in any more detail) to a cooling system, which is connected on the output side to the first ring line 28 for supplying cold cooling water WK, so that a closed cooling water circuit 34 is produced, which is indicated by arrows in the drawing.

Both the stator 8 and the rotor 6 can be cooled by means of cooling air L during operation of the generator 2. A cooling air cooler 36 is arranged on the stator 8 for this purpose. The cold cooling air L which emerges from the cooling air cooler 36 during operation of the generator 2 is supplied to the rotor 6, although this is not illustrated in the drawing. The cooling air L is heated in the rotor 6 and, as a result of the rotational movement of the rotor 6, flows to the stator 8, where it enters the cooling air cooler 36 once again, thus producing a closed cooling air circuit 38.

The critical variables 50 to be recorded for the generator 2 are the temperature value T₁₆ on the laminated core 16 of the stator 8, the temperature value T₁₈ on the winding 18 on the stator 8, the temperature value T_{LW} of the heated cooling air L for the stator 8, as it flows away from the stator 8, the temperature value T_{WK} of the cold cooling water WK before it enters the winding 18 on the stator 8, and the temperature value T_{WW} of the warm cooling water WW after it emerges from the winding 18 on the stator 8. Further critical variables 50 for the generator 2 are the temperature value T₁₄ of the winding 14 on the rotor 6, as well as the real power P and the wattless component Q of the generator 2.

A number of sensors 52 are arranged on the generator 2, in order to record the critical variables 50. In this case, a first group 54 of sensors 52 is arranged on the laminated core 16 of the stator 8 in order to record the temperature value T₁₆ on the laminated core 16 of the stator 8. A second group 56 of sensors 52 is arranged on the winding 18 on the stator 8 in order to record the temperature value T₁₈ of the winding 18 on the stator 10. A third group 58 of sensors 52 is arranged in the stator 8 in order to record the temperature value T_{LW} of the warm cooling air L flowing out of the stator 8. A fourth group 60 of sensors 52 is provided in the cooling water circuit 34 on the input side upstream of the first ring line 28, in order to record the temperature value T_{WK} of the cold cooling water WK before it enters the winding 18 on the stator 8. A fifth group 62 of sensors 52 is provided in the cooling water circuit 34, on the output side downstream from the second ring line 32, in order to record the temperature value T_{WW} of the warm cooling water WW after it emerges from the winding 18 on the stator 8. A module 64 is provided in order to determine by calculation the temperature value T₁₄ of the winding 14 on the rotor 6, and this module 64 determines the temperature value T₁₄ of the winding 14 on the rotor 6 from the electrical resistance of the winding 14 on the rotor 6 and from the loss from the current flowing through the winding 14 on the rotor 6. The real power P and wattless component Q of the generator 2, which are likewise provided as critical variables 50, are masked out via the isolating amplifiers 22 from existing measurement circuits which are connected to the connecting terminals 20 of the winding 14, but are not shown in the drawing. The sensors 52 for the critical variables 50 can be connected to the processing module 70 via data transmission connections 66.

The influencing variables 80 for the generator 2 are the current I and the voltage U of the stator 8, the field current I_{E} and the rotation speed N of the rotor 6, as well as the temperature value T_{LK} of the cold cooling air L flowing to the stator 8. The current I in the stator 8 is formed from the three current elements I_{U}, I_{V} and I_{W} in the windings U, V and W on the stator 8. The current elements I_{U}, I_{V} and I_{W} are measured using the measurement circuits, which are connected to the isolating amplifiers 22 but are not illustrated in the drawing. The voltage U of the stator 8 can also be masked out via the isolating amplifiers 22 from existing measurement circuits, which are not shown in any more detail in the drawing. The field current I_{E} for the rotor 6 and the rotation speed N of the rotor 6 can be recorded via a seventh group 82 and eighth group 84, respectively, of sensors 52, which are arranged in a suitable manner on the rotor 6. The temperature value T_{LK} of the cold cooling air L flowing to the stator 8 can be recorded via a ninth group 86 of sensors 52, which are arranged in the inlet flow region of the cold cooling air L for the stator 8. The influencing variables 80, that is to say the current elements I_{U}, I_{V} and I_{W} of the current I and the voltage U of the stator 8, the field current I_{E} and the rotation speed N of the rotor 6 as well as the temperature value T_{LK} of the cold cooling air L flowing to the stator 8, can likewise be supplied to the processing module 70 via data transmission connections 88.

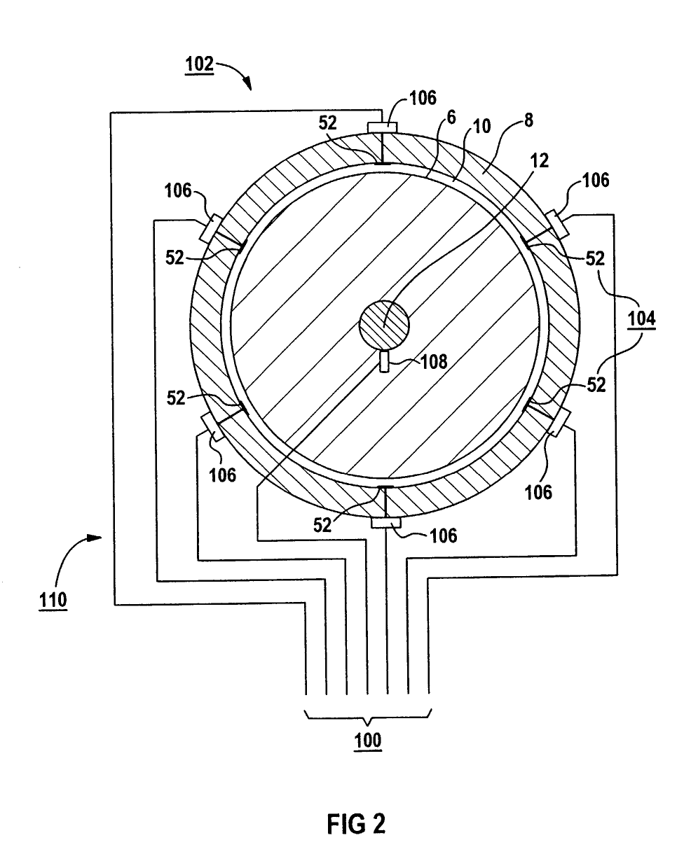

Three measurement planes 102, which are each at right angles to the rotation axis and at right angles to the shaft 12 of the rotor 6, are provided for recording the instantaneous measurement data 100 for the radial gap 10. However, depending on the configuration of the system, it may also be necessary for more or less than three measurement planes to be provided. In this case, the further measurement planes should also be arranged parallel to the shaft 12 of the rotor 6. The instantaneous measurement data 100 for the radial gap 10 is recorded by means of a tenth group 104 of sensors 52, six of which are arranged in the measurement plane 102 illustrated in FIG. 2 and two of which are in each case arranged in the further measurement planes 102 which are not illustrated. The arrangement of the six sensors 52 in the tenth group 104 in the measurement plane 102, which is arranged in the central plane of the stator, is shown in FIG. 2, which, in the form of a cross section, illustrates the detail annotated by X in FIG. 1. The sensors 52 for the other measurement planes 102 are arranged in a comparable manner, but with there being only two sensors.

As shown in FIG. 2, measurement data 100 for the radial gap 10 is recorded by means of six sensors 52 in the tenth group 104 which are arranged on the inner envelope surface of the laminated core 16 in a plane which is parallel to the shaft 12 of the rotor 8. The sensors 52 are each connected to an instrument transformer or conditioner 106, which is arranged on the outer envelope surface of the laminated core 16. Furthermore, a key phasor or a phase mark 108 is arranged on the shaft 12 of the rotor 6. If one of the six sensors 52 now measures a specific distance between one pole of the rotor 6 and the stator 8 during operation of the generator 2, then it is possible by means of the signal recorded via the phase mark 108 to electronically identify that pole which is being used for the measurement. The measurement data 100 for the radial gap 10 in the generator 2 can likewise be supplied to the processing module 70 via a data transmission connection 110, as is illustrated in FIG. 1.

The processing module 70 is provided for calculating instantaneous characteristic variables 120 from the instantaneous critical variables 50, the instantaneous influencing variables 80 and the instantaneous measurement data 100. To do this, the processing module 70 has a computer module 122, to which the critical variables 50, the influencing variables 80 and the measurement data 100 can be supplied. Analog/digital conversion of the recorded data as well as limit value monitoring or plausibility checking are also carried out in the processing module 70. The processing module 70 is also used for constructing data messages and to form signals for warnings, defects and disturbances.

The processing module 70 is connected to an analysis module 126 via a data bus 124. The processing module 70 and the analysis module 126 are part of the apparatus 128, which is used to monitor the radial gap 10 between the rotor 6 and the stator 8 of the electrical generator 2 during the operation of the generator 2.

The analysis module 126 has a memory module 130, a fingerprint module 132 and a monitoring module 134. The memory module 130 has a long-term memory, a monthly memory and an event memory for storing recorded data, characteristic variables 120 which have been determined, and measurement cycles that have been carried out as well as their results. The fingerprint module 132 is used to control basic measurements, by means of which reference values are determined for the generator 2 in specific operating states. The monitoring module 134 is intended for controlling measurement cycles which can be carried out on the generator 2, and for controlling their evaluation. For these functions, the monitoring module 134 communicates with the memory module 130, with the fingerprint module 132 and, via the data bus 124, with the processing module 70. Records and graphics of the measured data can also be produced by means of the analysis module 126. Furthermore, the analysis module 126 can signal to the system operator that a computer failure has occurred and/or that one or more of the characteristic variables 120 has or have exceeded a limit value.

During operation of the generator 2 the shape of the radial gap 10 and the distance between the rotor 6 and the stator 8 are analyzed, with attention being paid in particular to the minimum distance between the rotor 6 and the stator 8. This is done by carrying out a measurement cycle at regular time intervals during which the measurement variables 100 for the radial gap 10 are recorded instantaneously and are analyzed. Each measurement cycle lasts for a predetermined time T and is repeated immediately once the time T has elapsed, so that one measurement cycle follows another without any interruption.

Each measurement cycle is controlled by the monitoring module 134 and, in this exemplary embodiment, lasts for 30 minutes. The influencing variables 80 are read at the time t=T₀. The influencing variables 80 are the three current elements I_{U}, I_{V} and I_{W} in the windings U, V and W on the stator 8, the voltage U of the stator 8, the field current I_{E} and the rotation speed N of the rotor 6 as well as the temperature value T_{LK} of the cold cooling air L flowing to the stator 8. The influencing variables 80 are passed via the data transmission connections 88 to the processing module 70. In the processing module 70, the influencing variables 80 which have been read in are processed such that they can be supplied via the data bus 124 to the analysis module 126. After they have been processed, the processed influencing variables 80A are supplied to the analysis module 126. A check of the operating state of the generator 2 is then carried out in the analysis module 126 by means of the processed influencing variables 80A, using the modules arranged in the analysis module 126.

During the check of the operating state of the generator 2, a check is carried out to determine whether the generator 2 is in a first thermally steady state, in a second state which is a steady state but is not an equilibrium state, or is in a third state. A steady equilibrium operating state of the generator 2 exists when the influencing variables 80 are sufficiently constant throughout a configurable time, which in this exemplary embodiment is 10 minutes as standard. A third state of the generator 2 is a possible state of the generator 2 which is not equal to the first or second state of the generator. This may be, in particular, a so-called load ramp or load change on the generator 2 which has not yet been completed. If the check shows that the generator 2 is in a third state, then the measurement cycle is terminated, and is automatically re-started after 30 minutes. The measurement cycle is continued at a time t=T₁ only when the generator is in a first thermally steady state or is in a second state which is a steady state but is not an equilibrium state.

For each measurement cycle, the monitoring module 134 controls the reading of the measurement data 100 for the radial gap 10 and for the critical variables 50 at a time t=T₁. The measurement data 100 in this case comprises the signals from the six sensors 52 in the tenth group 104, which are arranged in the central measurement plane 102 and the signal for the phase mark 108. The signals from the sensors 52 in the tenth group 104 in the upper and the lower measurement plane 102 are used only for checking purposes. The measurement data 100 for the radial gap 10 is also processed in the processing module 70 so that this data can be read by the analysis module 126. The processed measurement data 100A is then supplied to the analysis module 126. The critical variables 50 are likewise read in, are supplied to the processing module 70 for processing, and are then fed to the analysis module 126 as processed critical variables 50A. The critical variables 50 are the temperature value T₁₆ on the laminated core 16 of the stator 8, the temperature value T₁₈ on the winding 18 on the stator 8, the temperature value T_{LW} of the heated cooling air L (flowing away from the stator 8) for the stator 8, the temperature value T_{WK} of the cold cooling water WK before it enters the winding 18 on the stator 8, and the temperature value T_{WW} of the warm cooling water WW after it emerges from the winding 18 on the stator 8. The other critical variables 50 for the generator 2 are the temperature value T₁₄ of the winding 14 on the rotor 6, as well as the real power P and the wattless component Q of the generator 2.

The analysis module 126 uses the processed measurement data 100A, the processed critical variables 50A and the processed influencing variables 80A in the monitoring module 134 to carry out a check to determine whether the generator 2 is still in a first thermally steady state or is in a second state which is a steady state but is not an equilibrium state. For this purpose, a check is carried out, inter alia, to determine whether the processed measurement data 100A is within a predetermined tolerance band.

If the generator 2 is in a first thermally steady state or is in a second state which is a steady state but is not an equilibrium state, after the recording and processing of the measurement data 100 for the radial gap 10, then the measurement cycle is continued at a time t=T₂. If the generator 2 is in a thermally stable state after this check, then the recorded data is analyzed, and if the generator 2 is in a state which is a steady state but is not an equilibrium state, then a substitute analysis is carried out, and if the generator 2 is in some other possible state, the measurement cycle is terminated. The measurement cycle is thus terminated at the time t=T₁ or t=T₂ if the generator 2 is in a third possible state.

Characteristic variables 120 are determined in the processing module 70 from the critical variables 50, from the influencing variables 80 and from the measurement data 100, for the analysis or the substitute analysis of the recorded data. The characteristic variables 120 determined at that time in the respective measurement cycle are compared in the analysis module 126 with reference values for the analysis or substitute analysis.

The reference values are determined during the so-called fingerprint recording for the generator 2, and are updated only when repair measures have resulted in changes to the generator 2, that is to say by way of example to the rotor 6, to the stator 8 or to the cooling water circuit 34. The reference values are determined and stored by means of the fingerprint module 132. The reference values are determined by carrying out measurement runs with the generator 2 in well-defined operating states. Well-defined operating states of the generator 2 are in this case, for example, states when the real power P from the generator 2 is at a minimum or maximum, as well as two further power levels, which are located at uniform intervals between the minimum and the maximum real power P of the generator 2. In addition, three measurement runs may be sufficient in this case, if the power range is small. In this case, before starting each measurement run, the influencing variables 80 must be constant within a configurable tolerance band. In addition, the critical variables must be documented manually, unless they are recorded automatically. In this case, the sequence of the measurement points is defined on a system-specific basis, for example taking into account the requirements of the load distributor and/or the starting program for the system.

The analysis or substitute analysis of the shape of the radial gap 10 and of the distance between the rotor 6 and the stator 8 is carried out by comparing the instantaneous characteristic variables 120 with the reference values. The result of the comparison is used to calculate the shape of the radial gap 10 and the distance between the rotor 6 and the stator 8. The mean size G of the radial gap 10, the shift V of the stator 8 relative to the shaft 12 of the rotor 6 and the deformation 0 of the stator 8 are determined in this case. Furthermore, during the analysis or substitute analysis, the shape of the radial gap 10 is analyzed on the basis of the mean size of the radial gap 10, the shift V of the stator 8 relative to the shaft 12 of the rotor 6 and the deformation O of the stator 8, in order to determine whether any changes to these variables over the course of time may have a negative effect on the operation of the generator. In particular, the minimum separation between the rotor 6 and the stator 8 is checked. If the separation between the rotor 6 and the stator 8 is too small, there is a risk of the rotor 6 making contact with the stator 8 during operation of the generator 2, which can cause major damage to the generator 2.

If the characteristic variables 120 are within a predetermined value range, then operation of the generator 2 continues without any change. If, in contrast, at least one of the instantaneously determined characteristic variables 120 is outside a predetermined value range, then the result of the analysis or substitute analysis is signaled via a signal to the operator of the generator 2, so that the operator can react to the respective change to the state of the generator 2. The infringement of limit values in a substitute analysis is in this case of lesser importance than such an infringement in an analysis relating to a first thermally steady state of the generator 2. The substitute analysis is intended only to identify any changes to the state of the generator 2 at an early stage.

The instantaneously recorded critical variables 50, the instantaneously recorded influencing variables 80, the instantaneously recorded measurement data 100, the instantaneous determined characteristic variables 120 and the instantaneous mean size G of the radial gap 10, the instantaneous shift V of the stator 8 relative to the shaft 12 of the rotor 6, the instantaneous deformation O of the stator 8 and further determined or recorded data in the measurement cycle are supplied to the memory module 130, where these variables are stored for documentation purposes. In the process, the time at which the data was recorded or determined is also recorded. The memory module 130 is used to process the result of the analysis or substitute analysis as well as the time profile of the critical variables 50, of the influencing variables 80, of the measurement data 100 and of the characteristic variables 120 in record form, so that trend analyses and graphical representations of the recorded and analyzed variables can be produced.

The measurement cycle is terminated, and a new measurement cycle is started, at a time t=T once the analysis or substitute analysis of the recorded and determined variables has been completed. This is the situation after 30 minutes in this exemplary embodiment. Carrying out a measurement cycle regularly every thirty minutes during operation of the generator 2 ensures that the shape of the radial gap 10 between the rotor 6 and the stator 8 and the separation between the rotor 6 and the stator 8 are analyzed in a particularly reliable manner, with the minimum separation between the rotor 6 and the stator 8 being checked in particular.

The apparatus 128 for monitoring the radial gap 10 between the rotor 6 and the stator 8 of the electrical generator 2 thus makes it possible to analyze the shape of the radial gap 10 between the rotor 6 and the stator 8 during operation of the generator 2, and to monitor the minimum separation between the rotor 6 and the stator 8. To do this, the instantaneous critical variables 50 for the generator 2, the instantaneous influencing variables 80 for the generator 2 and the instantaneous measurement data 100 for the radial gap 10 are used to determine the mean size G of the radial gap 10, the instantaneous shift V of the stator 8 relative to the shaft 12 of the rotor 6 and the instantaneous deformation V of the stator 10, provided the generator 2 is in a first thermally steady state or is in a second operating state, which is a steady state but is not an equilibrium state. In this way, changes in the generator 2 which are detrimental to operation of the generator 2 are identified and rectified at an early stage. This ensures disturbance-free operation of the generator 2 in a particularly reliable manner.

1. A method for monitoring the radial gap (10) between the rotor (6) and the stator (8) of an electrical machine, characterized by the following steps:
a) influencing variables (80) which govern the operating state are in each case recorded, basic measurements are carried out, and basic reference characteristic variables for the intact air gap geometry measured in the respective operating state are formed in advance for various defined operating states;
b) during subsequent operation, the size of the radial gap (10) is recorded at a number of measurement points, which are distributed around the circumference of the machine, and at least one instantaneous influencing variable (80) of the instantaneous operating state is recorded;
c) the variables (100), (80) obtained in step b) are used to form instantaneous characteristic variables (120), and the basic reference characteristic variables obtained in step a) are used to form instantaneous reference characteristic variables, which correspond to an intact air gap for the instantaneous values of the influencing variables (80);
d) at least the instantaneous characteristic variables (120) obtained in step c) are compared with the corresponding instantaneous reference characteristic variables of the radial gap; and if at least one of the instantaneous characteristic variables (120) differs from the reference characteristic variable by more than a specified amount, a warning is produced.

2. The method as claimed in claim 1, characterized in that the instantaneous measurement data (100) is recorded when the electrical machine is in a steady and equilibrium operating state.

3. The method as claimed in claim 1 or 2, characterized in that the instantaneous measurement data (100) and influencing variables (80) are recorded cyclically, and both the instantaneous characteristic variables (120) and the corresponding instantaneous reference characteristic variables are formed in each measurement cycle.

4. The method as claimed in one of claims 1 to 3, characterized in that at least one of the following operating parameters of the electrical machine is recorded as the influencing variable (80):
the currents (Iᵤ, Iᵥ, I_{w}) flowing in the windings on the stator
the current (I_{E}) flowing in the winding on the rotor
the temperature (T_{LK}) of the cold cooling air (L) flowing to the stator.

5. The method as claimed in one of claims 1 to 4, characterized in that a mathematical model for Fourier analysis is applied to first mathematical vectors which, for each measurement point, contain the instantaneous measurement values (100) of the air gap between the stator and the rotor poles moving past it during one revolution; in that at least one of the coefficients calculated on the basis of the Fourier analysis is used to form at least one further instantaneous characteristic variable and in that corresponding basic reference characteristic variables are obtained for the radial gap by corresponding application of Fourier analysis to the basic measurement values.

6. The method as claimed in claim 5, characterized in that the first coefficient, which corresponds to the DC component of the Fourier analysis, the second coefficient, which corresponds to the fundamental frequency, and the third coefficient, which corresponds to the first harmonic, are used to form further instantaneous characteristic variables, with the mean value of the first coefficients which are calculated for each vector describing the mean size of the radial gap (10), the mean value of each of the second coefficients describing the mean shift of the rotor axis relative to the axis of the stator (“eccentricity of the rotor”), and the mean value of each of the third coefficients describing the mean deformation of the rotor (“ovality of the rotor”).

7. The method as claimed in claim 6, characterized in that the already determined characteristic variables are used to derive an auxiliary characteristic variable which makes it possible to estimate whether the further instantaneous characteristic variables describe the deformation of the rotor sufficiently accurately.

8. The method as claimed in claim 7, characterized in that, if the values of the auxiliary characteristic variable are significant, at least one requirement characteristic variable is formed from at least one further coefficient obtained by means of the Fourier analysis.

9. The method as claimed in one of claims 5 to 8, characterized by the application of a mathematical model for Fourier analysis to a second mathematical vector having vector components which each correspond to one measurement point and each of which contains the mean value of the size of the radial gap (10) associated with that measurement point, with at least one additional instantaneous characteristic variable being formed from at least the second coefficients calculated on the basis of the Fourier analysis and corresponding instantaneous reference characteristic variables of the radial gap being obtained by corresponding application of the Fourier analysis to the averaged basic reference characteristic variables associated with each measurement point.

10. The method as claimed in claim 9, characterized in that the additional instantaneous characteristic variables are formed from the second and third coefficients calculated on the basis of the Fourier analysis of the second vector.

11. The method as claimed in one of claims 1 to 10, characterized in that the instantaneous measurement data (100) for the radial gap (10) is recorded in a measurement plane (102) the normal to whose surface is oriented parallel to the shaft (12) of the rotor (6).

12. The method as claimed in one of claims 1 to 11, characterized in that at least one critical variable (50) is also recorded in addition to the influencing variables (80) which describe the instantaneous operating state of the electrical machine.

13. The method as claimed in claim 12, characterized in that at least one of the following variables is recorded as the critical variable (50):
the temperature (T₁₆) of the laminated stator core
the temperature (T₁₈) of the stator winding
the temperature (T_{LW}) of the hot cooling air flowing away from the stator
the temperature (T_{WK}) of the cold cooling water before it enters the stator winding
the temperature (T_{WW}) of the warm cooling water emerging from the winding on the stator
the temperature of the rotor winding
the wattless component of the electrical machine
the real power of the electrical machine

14. The method as claimed in claim 12 or 13, characterized in that the critical variables (50) are used for more detailed analysis of the instantaneous characteristic variables (120).

15. The method as claimed in one of claims 1 to 14, characterized in that at least each measurement of the instantaneous measurement data (100), of the influencing variables (80) and of the critical variables (50) as well as all the characteristic variables (120) determined for one measurement are documented.

16. A method for monitoring the radial gap (10) between the rotor (6) and the stator (8) of an electrical generator (2), in which a measurement cycle is carried out at fixed time intervals when the generator (2) is in a steady and equilibrium operating state, in which case, during the measurement cycle:
instantaneous influencing variables (80) of the generator (2) are recorded,
instantaneous measurement data (100) are recorded for the radial gap (10) and instantaneous critical variables (50) are recorded for the generator (2),
instantaneous characteristic variables (120) for the radial gap (10) are determined from the instantaneous critical variables (50) for the generator (2), from the instantaneous influencing variables (80) for the generator (2) and from the instantaneous measurement data (100) for the radial gap (10), and
the shape of the radial gap (10) and the distance between the rotor (6) and the stator (8) are determined and assessed by comparing the instantaneous characteristic variables (120) for the radial gap (10) with reference values from a number of basic measurements.

17. The method as claimed in claim 16, in which the shift (V) of the stator (8) relative to the shaft (12) of the rotor (6) is determined.

18. The method as claimed in claim 16 or 17, in which the deformation (O) of the stator (8) is determined.

19. The method as claimed in one of claims 16 to 18, in which temperature values (T₁₆, T₁₈, T_{LW}, T_{WK}, T_{WW}) at different locations on the stator (8), the temperature value (T₁₄) of the winding (14) on the rotor (6), the real power (P) and the wattless component (Q) of the generator (2) are determined as critical variables (50) for the generator (2).

20. The method as claimed in claim 19, in which the temperature value (T₁₆) on the laminated core (16) of the stator (8), the temperature value (T₁₈) on the winding (18) on the stator (8), the temperature value (T_{LW}) of the warm cooling air (L) flowing away from the stator (8), the temperature value (T_{WK}) of the cold cooling water (WK) before it enters the winding (18) on the stator (8), and the temperature value (T_{WW}) of the warm cooling water (WK) after it emerges from the winding (18) on the stator (8) are determined as temperature values (T₁₆, T₁₈, T_{LW}, T_{WK}, T_{WW}) at different locations on the stator (8).

21. The method as claimed in one of claims 16 to 20, in which the current (I) and the voltage (U) of the stator (8), the field current (I_{E}) and the rotation speed (N) of the rotor (6), and the temperature (T_{LK}) of the cold cooling air (L) flowing to the stator (8) are recorded as instantaneous influencing variables (80) for the generator (2).

22. The method as claimed in one of claims 16 to 21, in which the instantaneous measurement data (100) for the radial gap (10) is determined in a measurement plane (102) which is at right angles to the shaft (12) of the rotor (6).

23. The method as claimed in one of claims 16 to 22, in which each measurement cycle is documented.

24. An apparatus (128) for monitoring the radial gap (10) between the rotor (6) and the stator (8) of an electrical generator (2), in which a number of sensors (52) are provided in order to record instantaneous critical variables (50) for the generator (2), instantaneous influencing variables (80) for the generator (2), and instantaneous measurement data (100) for the radial gap (10), in which the sensors (52) are connected, for data transmission purposes, to a processing module (70) which is provided in order to produce instantaneous characteristic variables (120) from the instantaneous critical variables (50) for the generator (2), from the instantaneous influencing variables (80) for the generator (2) and from the instantaneous measurement data (100) for the radial gap (10), with the processing module (70) being connected, for data transmission purposes, to an analysis module (126), in which case the analysis module (126) can control a measurement cycle for analysis of the shape of the radial gap (10) and for monitoring the distance between the rotor (6) and the stator (8).

25. The apparatus as claimed in claim 24, in which the analysis module (126) has a memory module (130).
